(19) United States
(12) Patent Application Publication
(10) Pub. No.: US 2026/0271302 A1
(43) Pub. Date: Sep. 10, 2026

(54) ETCH STOP LAYER FOR MRAM

(71) Applicant: INTERNATIONAL BUSINESS MACHINES CORPORATION, ARMONK, NY (US)

(72) Inventors: Yann Mignot, Slingerlands, NY (US); Harsimranjit Singh, Niskayuna, NY (US); Sang-Kee Eah, Watervliet, NY (US); Nitin Prasad, Guilderland, NY (US); Chih-Chao Yang, Glenmont, NY (US); Shravana Kumar Katakam, Lehi, UT (US); SON NGUYEN, Schenectady, NY (US)

(21) Appl. No.: 19/070,902

(22) Filed: Mar. 5, 2025

(51) Int. Cl. H10B 61/00

(52) U.S. Cl. CPC H10B 61/10

(57) ABSTRACT

A magnetoresistive-random-access-memory (MRAM) cell array that includes a plurality of MRAM cells. A plurality of connecting vias, where each of the plurality of the connecting vias is connected one of the plurality of MRAM cells. A first dielectric layer located adjacent to a bottom section of the plurality of connecting vias. An etch stop layer located on top of the first dielectric layer, where the etch stop layer has a varying thickness. A second dielectric layer located directly adjacent to an upper section of the plurality of connecting vias, where the second dielectric layer is direct contact with a portion of the etch stop layer.

### BACKGROUND

The present invention generally relates to the field of microelectronic devices, and more particularly to controlling an over etching in MRAM arrays to prevent shorts and defects from developing.

Nanosheet is the lead device architecture in continuing CMOS scaling are fabricated on the same chip/wafer as MRAM. The height difference between different devices on the same chip/wafer can have different process window margins for opens/shorts due to differences in overetching time. Meaning that the normal process for one part of the device can lead to an open/short being formed in another part of the device.

### BRIEF SUMMARY

Additional aspects and/or advantages will be set forth in part in the description which follows and, in part, will be apparent from the description, or may be learned by practice of the invention.

A magnetoresistive-random-access-memory (MRAM) cell array that includes a plurality of MRAM cells. A plurality of connecting vias, where each of the plurality of the connecting vias is connected one of the plurality of MRAM cells. A first dielectric layer located adjacent to a bottom section of the plurality of connecting vias. An etch stop layer located on top of the first dielectric layer, where the etch stop layer has a varying thickness. A second dielectric layer located directly adjacent to an upper section of the plurality of connecting vias, where the second dielectric layer is direct contact with a portion of the etch stop layer.

A magnetoresistive-random-access-memory (MRAM) cell array that includes a plurality of MRAM cells. A plurality of connecting vias, where each of the plurality of the connecting vias is connected one of the plurality of MRAM cells. A first dielectric layer located adjacent to a bottom section of the plurality of connecting vias. An etch stop layer located on top of the first dielectric layer, where a first portion of the etch stop layer is comprised of multiple layers, where a second portion of the etch stop layer is comprised of fewer layer than the first portion. A second dielectric layer located directly adjacent to an upper section of the plurality of connecting vias, where the second dielectric layer is direct contact with a portion of the etch stop layer.

A method of forming a magnetoresistive-random-access-memory (MRAM) cell array that includes the steps of forming a plurality of connecting vias. Forming a first dielectric layer located adjacent to a bottom section of the plurality of connecting vias and forming an etch stop layer located on top of the first dielectric layer. Forming a second dielectric layer located directly adjacent to an upper section of the plurality of connecting vias and forming a bottom electrode layer on top of the second dielectric layer and the plurality of connecting vias. Forming a magnetic-tunnel-junction (MTJ) layer on top of the bottom electrode and forming a top electrode layer on the MTJ layer. Utilizing an etching process to form a plurality of MRAM cells, where the etching process causes variations in a thickness of the etch stop layer.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1 illustrates a cross-section of an MRAM array after the initial processing, in accordance with an embodiment of the present invention.

FIGS. 2A and 2B illustrate a cross-section of the MRAM array after an etching process to form the MRAM cells, in accordance with an embodiment of the present invention.

FIGS. 3A and 3B illustrate a cross-section of the MRAM array after formation of a spacer layer, in accordance with an embodiment of the present invention.

FIGS. 4A, 4B, and 4C, illustrate a cross-section of the MRAM array after additional processing, in accordance with an embodiment of the present invention.

### DETAILED DESCRIPTION

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and the words used in the following description and the claims are not limited to the bibliographical meanings but are merely used to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is understood that the singular forms “a,” “an,” and “the” include plural referents unless the context clearly dictates otherwise. Thus, for example, reference to “a component surface” includes reference to one or more of such surfaces unless the context clearly dictates otherwise.

Detailed embodiments of the claimed structures and the methods are disclosed herein: however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the present embodiments.

References in the specification to “one embodiment,” “an embodiment,” an example embodiment,” etc., indicate that the embodiment described may include a particular feature, structure, or characteristic, but every embodiment may not include the particular feature, structure, or characteristic. Moreover, such phrases are not necessarily referring to the same embodiment. Further, when a particular feature, structure, or characteristic is described in connection with an embodiment, it is submitted that it is within the knowledge of one of ordinary skill in the art o affect such feature, structure, or characteristic in connection with other embodiments whether or not explicitly described.

For purpose of the description hereinafter, the terms “upper,” “lower,” “right,” “left,” “vertical,” “horizontal,” “top,” “bottom,” and derivatives thereof shall relate to the disclosed structures and methods, as orientated in the drawing figures. The terms “overlying,” “atop,” “on top,” “positioned on,” or “positioned atop” mean that a first element, such as a first structure, is present on a second element, such as a second structure, where intervening elements, such as an interface structure may be present between the first element and the second element. The term “direct contact” means that a first element, such as a first structure, and a second element, such as a second structure, are connected without any intermediary conducting, insulating, or semiconductor layer at the interface of the two elements.

In the interest of not obscuring the presentation of embodiments of the present invention, in the following detailed description, some processing steps or operations that are known in the art may have been combined for presentation and for illustrative purposes and in some instance may have not been described in detail. In other instances, some processing steps or operations that are known in the art may not be described at all. It should be understood that the following description is rather focused on the distinctive features or elements of various embodiments of the present invention.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or indirect coupling, and a positional relationship between entities can be direct or indirect positional relationship. As an example of indirect positional relationship, references in the present description to forming layer “A” over layer “B” includes situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains,” or “containing” or any other variation thereof, are intended to cover a non-exclusive inclusion. For example, a composition, a mixture, process, method, article, or apparatus that comprises a list of elements is not necessarily limited to only those elements but can include other element not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiment or designs. The terms “at least one” and “one or more” can be understood to include any integer number greater than or equal to one, i.e., one, two, three, four, etc. The terms “a plurality” can be understood to include any integer number greater than or equal to two, i.e., two, three, four, five, etc. The term “connection” can include both indirect “connection” and a direct “connection.”

As used herein, the term “about” modifying the quantity of an ingredient, component, or reactant of the invention employed refers to variation in the numerical quantity that can occur, for example, through typical measuring and liquid handling procedures used for making concentrations or solutions. Furthermore, variation can occur from inadvertent error in measuring procedures, differences in manufacture, source, or purity of the ingredients employed to make the compositions or carry out the methods, and the like. The terms “about” or “substantially” are intended to include the degree of error associated with measurement of the particular quantity based upon the equipment available at the time of the filing of the application. For example, about can include a range of ±8%, or 5%, or 2% of a given value. In another aspect, the term “about” means within 5% of the reported numerical value. In another aspect, the term “about” means within 10, 9, 8, 7, 6, 5, 4, 3, 2, or 1% of the reported numerical value.

Various processes are used to form a micro-chip that will be packaged into an integrated circuit (IC) fall in four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE), and more recently, atomic layer deposition (ALD) among others. Removal/etching is any process that removes material from the wafer. Examples include etching process (either wet or dry), reactive ion etching (RIE), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implant dopants. Films of both conductors (e.g., aluminum, copper, etc.) and insulators (e.g., various forms of silicon dioxide, silicon nitride, etc.) are used to connect and isolate electrical components. Selective doping of various regions of the semiconductor substrate allows the conductivity of the substrate to be changed with the application of voltage.

Reference will now be made in detail to the embodiments of the present invention, examples of which are illustrated in the accompanying drawings, where like reference numerals refer to like elements throughout. The present invention is directed towards magnetoresistive-random-access-memory (MRAM) cells/arrays, more specifically to utilizing an etch stop layer to prevent over etching when forming the individual MRAM cells. The etch stop layer has a better selectivity and help to reduce ISO/DENSE RIE LAG effect. The etch stop layer can be comprised of one layer, two layers, three layers, or more layers. The etch stop layer can be located on the same level as the bottom via element or on the same level as the bottom electrode. The etch stop layer provides greater etch selectivity and reduces recess (RIE-LAG) during the MRAM elements fabrication. With improved oxide selectivity, downstream oxide refill will benefit of a better planarization preventing risk of structures short from top interconnects. When utilizing a single etch stop layer, the thickness will be in the range of about 2 nm to about 18 nm. When utilizing a dual layer etch stop layer, each of the layers will have a thickness in the range of about 2 nm to about 9 nm. When utilizing a tri-layer etch stop layer, each of the layers of the etch stop will have a thickness in the range of about 2 to 6 nm. As the number of layers of the etch stop layer increases, the thickness of each layer can be reduced. The etch stop layer just needs to be of a sufficient thickness to stop the etching process to prevent over etching.

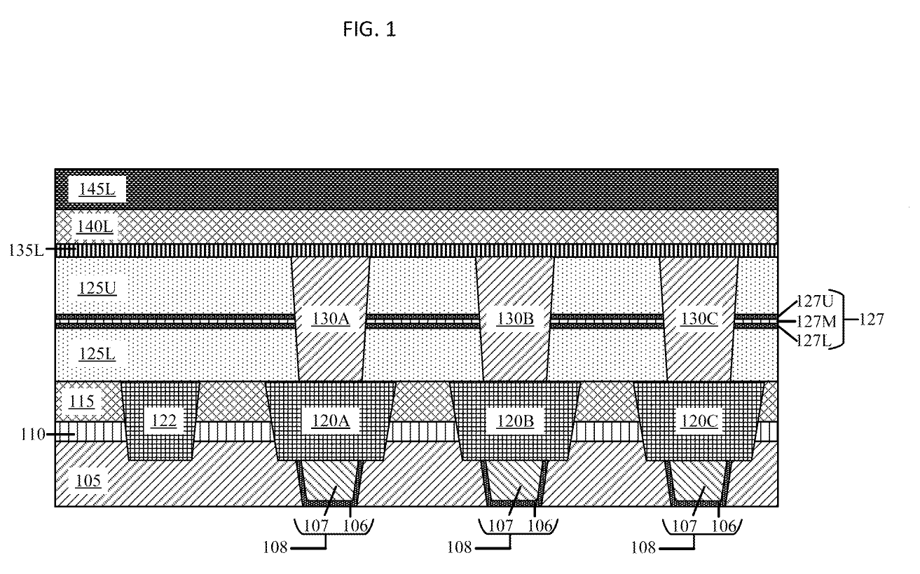

Referring now to FIG. 1, a structure is shown of a magnetoresistive-random-access-memory (MRAM) array during an intermediate step of forming the initial structure. The MRAM array is comprised of one or more MRAM cells and necessary electrical connections. FIG. 1 illustrates a portion of the MRAM array that includes a first layer 105, underlying connectors 108, a cap layer 110, an interlayer dielectric layer 115, a connector 122, a MRAM cell connector 120A, 120B, 120C, a lower dielectric layer 125L, a MRAM connecting via 130A, 130B, 130C, an etch stop layer 127, a upper dielectric layer 125U, a bottom electrode layer 135L, a magnetic-tunnel-junction (MTJ) layer 140L, and a top electrode layer 145L.

The first layer 105 can be a substrate, an oxide layer, an underlying device, or a suitable base for the formation of the MRAM array. The underlying connector 108 can include a liner 106 and a fill layer 107. The underlying connector 108 is an optional element that is present when a connection needs to be formed to each of the MRAM cell connectors based on the design/architecture of the underlying structure of the underlying devices.

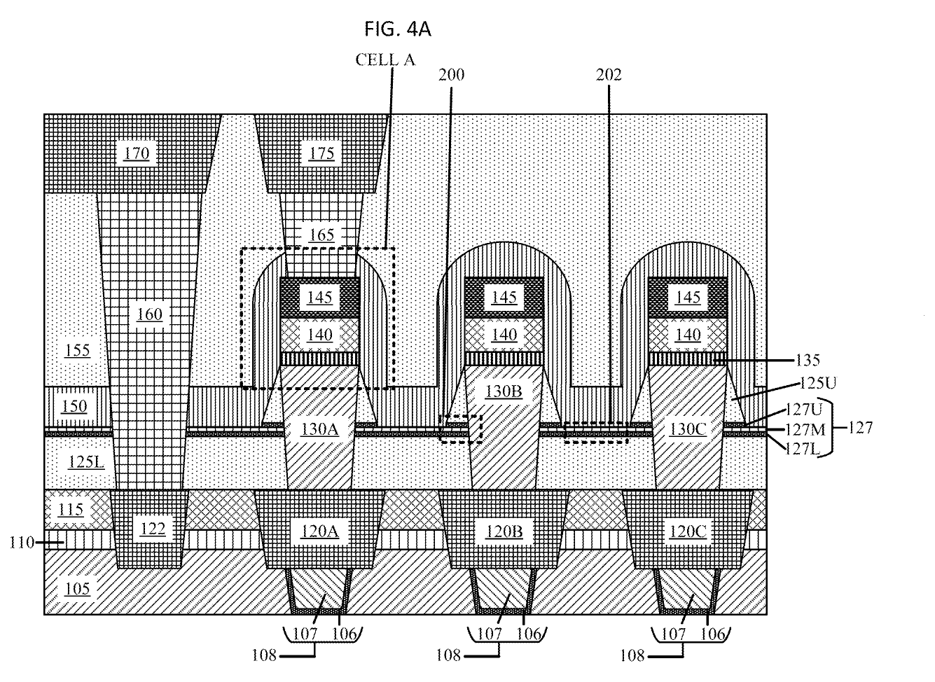

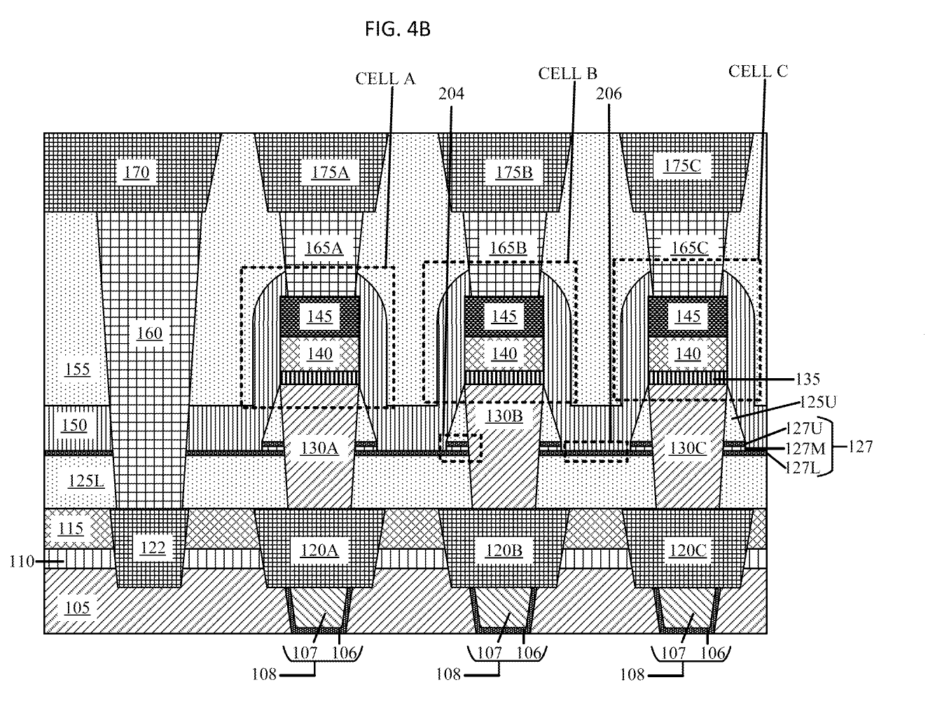

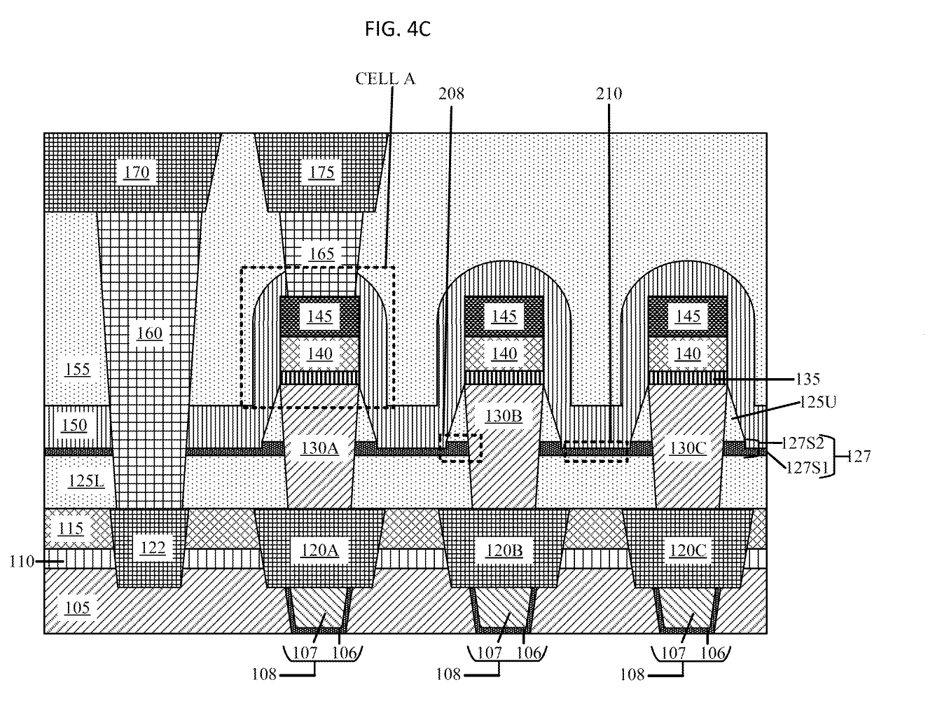

Connector 122 and MRAM cell connectors 120A, 120B, 120C are located in the first layer 105, the cap layer 110, and the interlayer dielectric layer 115. The MRAM cell connectors 120A, 120B, 120C are located above the optional underlaying connectors 108. The lower dielectric layer 125L is located on top of the interlayer dielectric layer 115, the connector 122 and MRAM cell connectors 120A, 120B, 120C. The lower dielectric layer 125L can be comprised of the same dielectric material as interlayer dielectric layer 115 or it can be comprised of a different dielectric material. Etch stop layer 127 is formed on top of the lower dielectric layer 125L. The etch stop layer 127 can be comprised of one layer, two layers, three layers, or more layers. FIGS. 1- 4B illustrate the situation where the etch stop layer 127 is comprised of three layers and FIG. 4C illustrates the situation where the etch stop layer 127 is comprised of one layer. For example, the three-layer etch stop layer 127 can be comprised of a lower layer 127L, a middle layer 127M, and an upper layer 127U. The lower layer 127L, the middle layer 127M, and the upper layer 127U can be comprised of the same materials, different materials, or a combination thereof.

When utilizing a single etch stop layer 127, the thickness will be in the range of about 2 nm to about 18 nm. When utilizing a dual layer etch stop layer 127 (where the dual layer etch stop layer 127 is not shown in the figures), each of the layers will have a thickness in the range of about 2 nm to about 9 nm. When utilizing a tri-layer etch stop layer 127, each of the layers 127L, 127M, 127U, of the etch stop layer 127 will have a thickness in the range of about 2 to 6 nm. As the number of layers of the etch stop layer 127 increases, the thickness of each of the layers can be reduced. The etch stop layer 127 just needs to be of a sufficient thickness to stop the etching process to prevent over etching into the lower dielectric layer 125L, or another layer located directly beneath the etch stop layer 127.

An upper dielectric layer 125U is located on top of the etch stop layer 127. A plurality of trenches (not shown) is formed in the upper dielectric layer 125U, the etch stop layer 127, and the lower dielectric layer 125L, where each of the trenches (not shown) exposes a top surface of one of the MRAM cell connectors 120A, 120B, 120C. These trenches (not shown) are filled with a conductive metal to form the MRAM connecting vias 130A, 130B, 130C. Each of the MRAM connecting vias 130A, 130B, 130C is connected to one of the MRAM cell connectors 120A, 120B, 120C. A bottom electrode layer 135L is located on top of the upper dielectric layer 125U and the MRAM connecting vias 130A, 130B, 130C. The magnetic tunnel junction (MTJ) layer 140L is located on top of the bottom electrode layer 135L. The top electrode layer 145L is located on top of the MTJ layer 140L.

The magnetic tunnel junction (MTJ) layer 140L is comprised of a plurality of layers. The individual layers of the MTJ layer 140L are not shown, but the MTJ layer 140L includes a reference layer, a tunnel barrier layer, and a free layer. The material for the reference layer can be selected from a group that includes CoFeB layers with Fe Co, Pt, or Ta. The tunnel barrier layer can be selected from a group that includes MgO or Al₂O₃. The free layer can be selected from a group that includes CoFeB multi-layers with Mo, Pt, or Ta. The bottom electrode layer 135L and the top electrode layer 145L can be selected from a group that includes Nb, NbN, W, WN, Ta, TaN, Ti, TiN, Ru, Cu, Co, W, Mo, Cr, V, Pd, Pt, Rh, Sc, Al, other high melting point metals, other suitable conductive metals, conductive alloys, or a combination thereof.

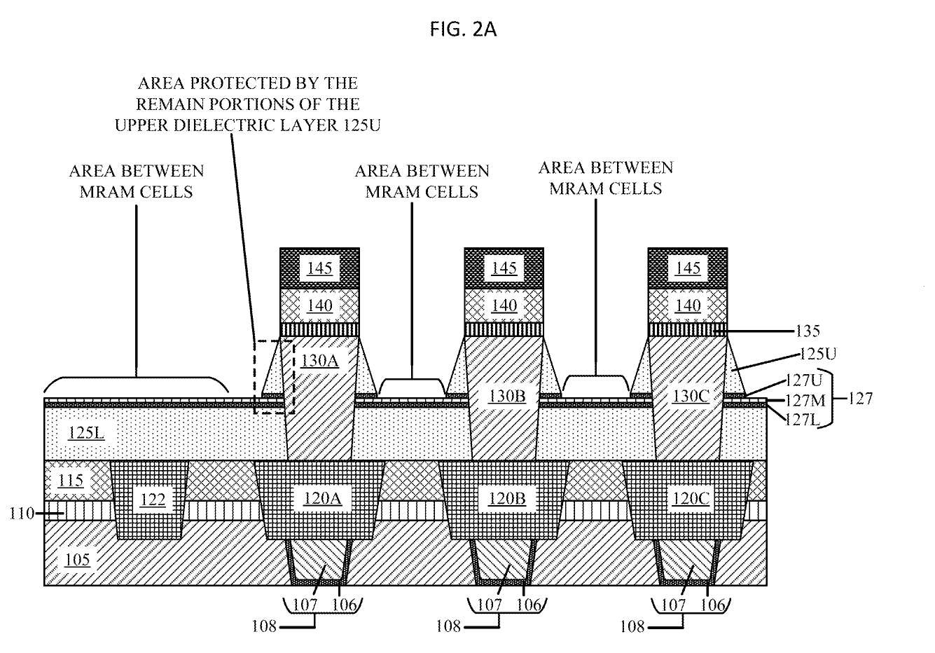

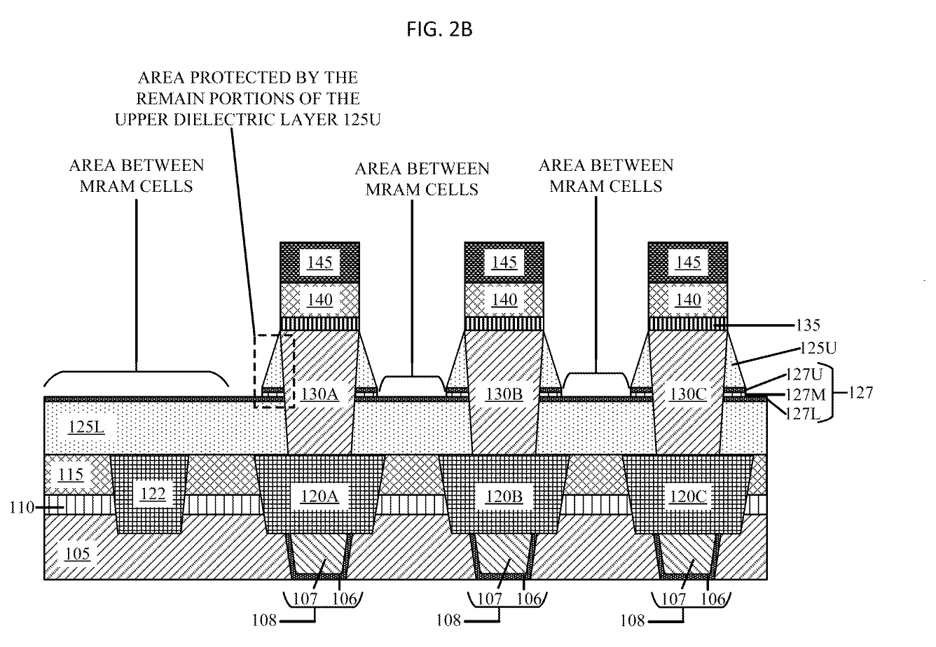

FIGS. 2A and 2B illustrates the processing stage after an etching process to form the MRAM cells of the MRAM array. The multiple layers are etched by, for example, an Ion Beam Etch (IBE) to form a plurality of MRAM cells. Each of the MRAM cells includes a portion of the top electrode layer 145L, which will now be referred to as the top electrode 145, a portion of the MTJ junction layer 140L, which will now be referred to as the MTJ junction 140, and a portion of the bottom electrode layer 135L, which will now be referred to as the bottom electrode 135. Each of the MRAM cells are located on top of one of the MRAM connecting vias 130A, 130B, 130C. A portion of the upper dielectric layer 125U is not removed, such that the remaining portion of the upper dielectric layer 125U is located adjacent to each of the MRAM connecting vias 130A, 130B, 130C. The etch stop layer 127 prevents the etching process from reaching the lower dielectric layer 125L. A portion of the etch stop layer 127 is removed by the etching process, thus creating variations in the thickness of the etch stop layer 127. The etch stop layer 127 will have a thinner area located where the etch top layer 127 interacted with the etching process and the etch stop layer 127 will have a thicker area that was protected by the remaining portions of the upper dielectric layer 125U. FIG. 2A illustrates the scenario where the upper layer 127U of the etch stop layer 127 is removed (i.e., the thinner area) in the areas located between each of the MRAM cells, e.g., the area of the etch stop layer 127 that interacted with the etching process. FIG. 2A further illustrates the etch stop layer 127 that was protected by the remaining portions of the upper dielectric layer 125U (i.e., the thicker area where the upper layer 127U of the etch stop layer 127 remains). FIG. 2B illustrates the scenario where the upper layer 127U and the middle layer 127M of the etch stop layer 127 are removed (i.e., the thinner area) in the areas located between each of the MRAM cells, e.g. the area of the etch stop layer 127 that interacted with the etching process. FIG. 2B further illustrates the etch stop layer 127 that was protected by the remaining portions of the upper dielectric layer 125U (i.e., the thicker area where the upper layer 127U and the middle layer 127M of the etch stop layer 127 remains). The etch stop layer 127 that is located beneath the remaining portions of the upper dielectric layer 125U has a first thickness and the etch stop layer 127 located between the MRAM cells has a second thickness. The first thickness is greater than the second thickness. The etch stop layer 127 prevents the etching process from interacting with the lower dielectric layer 125L, but the etching process causes variations in the thickness of the etch stop layer 127.

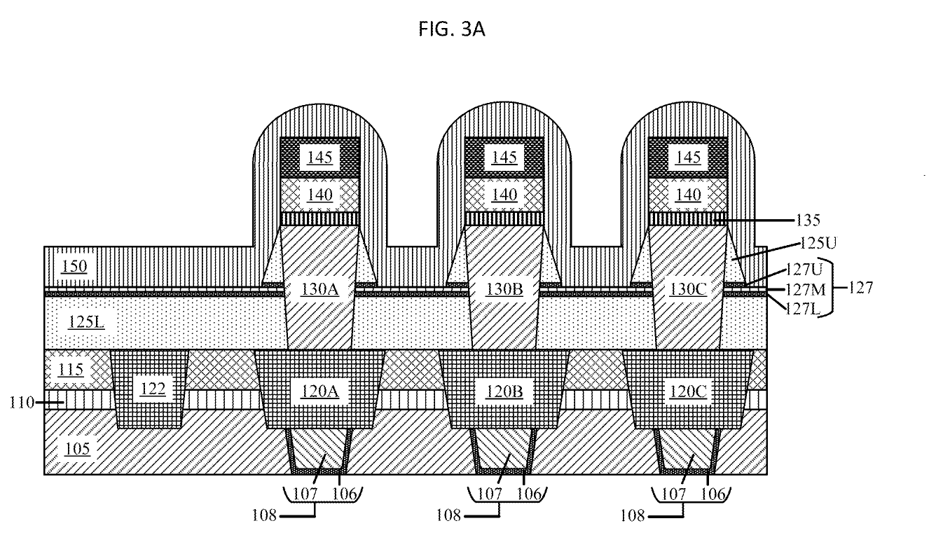

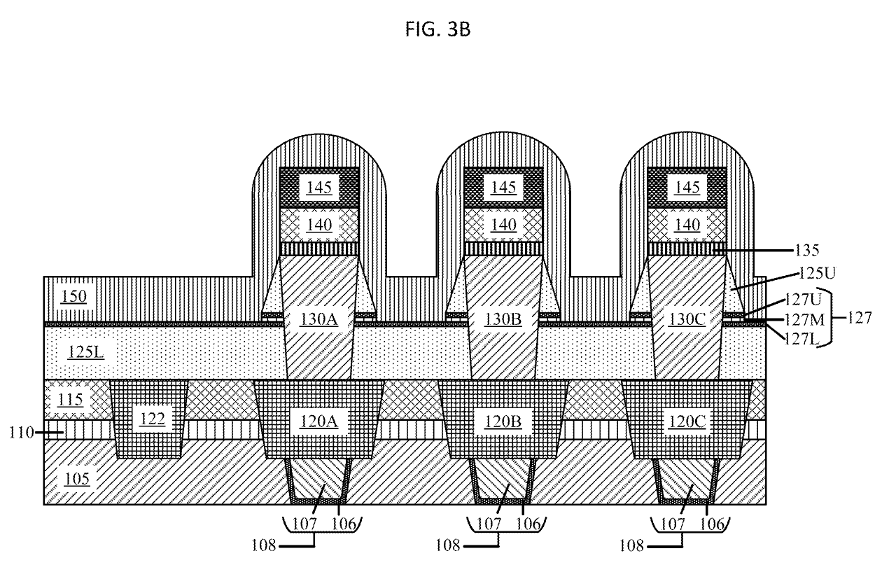

FIGS. 3A and 3B illustrate the processing stage after formation of the spacer layer 150. Spacer layer 150 is formed on the exposed surfaces of the MRAM cells and on the exposed surface of the etch stop layer 127. The spacer layer 150 can be comprised of a nitride, for example, SiN, an oxide, SiCO, SiNO, SiCBN or another suitable low k spacer material.

FIGS. 4A, 4B, and 4C, illustrate the processing stage after additional processing steps. FIGS. 4A, 4B, and 4C, illustrate different scenarios for the connection formation and different scenarios for the etch stop layer 127. FIGS. 4A, 4B, and 4C, illustrate that the lower dielectric layer 125L is in contact with a bottom portion of the MRAM connecting vias 130A, 130B, 130C and that the remaining portions of the upper dielectric layer 125U are in contact with a top portion of the MRAM connecting vias 130A, 130B. 130C. Furthermore, the spacer layer 150 is contact with a vertical side surface of the etch stop layer 127, specifically that the spacer layer 150 is contact with the vertical side surface of the etch stop layer 127 that is located beneath the remaining portion of the upper dielectric layer. See, for example, dashed boxes 200, 204, and 208.

FIG. 4A illustrates the formation of a second interlayer dielectric layer 155 located on top of the spacer layer 150. The second interlayer dielectric layer 155 can be comprised of the same dielectric material as interlayer dielectric layer 115 or can be comprised of a different dielectric material. A plurality of trenches (not shown) was formed and filled with a conductive metal to form a first contact via 160, a second contact via 165, a first contact 170, and a second contact 175. The first contact via 160 is connected to connector 122 and the first contact 170 is connected to the first contact via 160. The second contact via 165 is connected to the top electrode 145 of one of the MRAM cells, for example, cell A. The second contact 175 is connected to the second contact via 165. Dashed box 200 illustrates the section of the etch stop layer 127 that has a first thickness, i.e., the portion of the etch stop layer 127 that was protected by the remaining portions of the upper dielectric layer 125U. Dashed box 202 illustrates the section of the etch stop layer 127 located between MRAM cells that has a second thickness. The second thickness of the etch stop layer 127 was caused by the etching process to form the individual MRAM cells that comprise the array. The first thickness is equal to the thickness of the etch stop layer 127 prior to the etching process to form the individual MRAM cells. The first thickness is larger than the second thickness.

FIG. 4B illustrates a different scenario than FIG. 4A, where more connections vias 165A, 165B, 165C and more contacts 175A, 175B, 175C are formed. Additionally, FIG. 4B illustrates the scenario where portions of the middle layer 127M of the etch stop layer 127 is removed. The different scenarios of the etch stop layer 127 illustrated in FIGS. 4A and 4B is independent of the different wiring scenarios illustrated in FIGS. 4A, and 4B. The first cell connection via 165A is connected to the top electrode 145 of cell A, the second cell connection via 165B is connected to the top electrode 145 of cell B, and the third cell connection via 165C is connected to the top electrode 145 of cell C. The first cell contact 175A is connected to the first cell connection via 165A, the second cell contact 175B is connected to the second cell connection via 175B, and the third cell contact 175C is connected to the third cell connection via 165C. Dash box 204 is similar to dashed box 200 that emphasizes the portion of the etch stop layer 127 that was protected by portions of the upper dielectric layer 125U. Dashed box 206 emphasizes the section of the etch stop layer 127 that is located between MRAM cells where the upper layer 127U and the middle layer 127M of the etch stop layer 127 is removed, such that this section of the etch stop layer 127 has a third thickness. The first thickness of the etch stop layer 127 (i.e., the portion of the etch stop layer 127 that is emphasized by dashed box 204) is greater than the third thickness of the etch stop layer 127.

FIG. 4C illustrates a different scenario than FIG. 4A and FIG. 4B. FIG. 4C illustrates the scenario where the etch stop layer 127 is comprised of a single etch stop layer. The different scenarios of the etch stop layer 127 illustrated in FIGS. 4A, 4B, and 4C, is independent of the different wiring scenarios illustrated in FIGS. 4A, 4B, and 4C. FIGS. 4A and 4B illustrates the scenario where the etch stop layer 127 is comprised of three layers and where different amounts of the etch stop layer 127 that was removed during the MRAM cell etching process. Dash box 208 is similar to dashed box 200 that emphasizes the portion of the etch stop layer 127, i.e., section 127S2 that was protected by portions of the upper dielectric layer 125U. Section 127S2 of the etch stop layer 127 that was protected by the upper dielectric layer 125U has a fourth thickness, i.e, the thickness of the etch stop layer 127 prior to the etching process to form the individual MRAM cells. Dashed box 210 emphasizes the section of the etch stop layer 127, i.e., section 127S1, that is located between MRAM cells where the portions of the etch stop layer 127 was removed, such that this section 127S1 of the etch stop layer 127 has a fifth thickness. The fourth thickness of the etch stop layer 127 (i.e., section 127S2 of the etch stop layer 127) is greater than the fifth thickness of the etch stop layer 127 (i.e., section 127S1 of the etch stop layer 127). The wiring scenario illustrated in FIG. 4C is the same as the scenario illustrated in FIG. 4A, but it is obvious that a different wiring scenario (i.e., the one illustrated in FIG. 4B) or something else could have been utilized.

While the invention has been shown and described with reference to certain exemplary embodiments thereof, it will be understood by those skilled in the art that various changes in form and details may be made therein without departing from the spirit and scope of the present invention as defined by the appended claims and their equivalents.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the one or more embodiment, the practical application or technical improvement over technologies found in the marketplace, or to enable others of ordinary skill in the art to understand the embodiments disclosed herein.

What is claimed is:

1. A magnetoresistive-random-access-memory (MRAM) cell array comprising:
a plurality of MRAM cells;
a plurality of connecting vias, wherein each of the plurality of the connecting vias is connected one of the plurality of MRAM cells;
a first dielectric layer located adjacent to a bottom section of the plurality of connecting vias;
an etch stop layer located on top of the first dielectric layer, wherein the etch stop layer has a varying thickness; and
a second dielectric layer located directly adjacent to an upper section of the plurality of connecting vias, wherein the second dielectric layer is direct contact with a portion of the etch stop layer.

2. The MRAM cell array of claim 1, wherein a first portion of the etch stop layer that is located between the first dielectric layer and the second dielectric layer has a first thickness.

3. The MRAM cell array of claim 2, further comprising:
a spacer layer located on top of the etch stop layer.

4. The MRAM cell array of claim 3, wherein the spacer layer is in contact with a vertical side surface of the first portion of the etch stop layer.

5. The MRAM cell array of claim 4, wherein a second portion of the etch stop layer located between the first dielectric layer and the spacer layer has a second thickness, wherein the spacer layer is in direct contact with the etch stop layer.

6. The MRAM cell array of claim 5, wherein the first thickness is greater than the second thickness.

7. A magnetoresistive-random-access-memory (MRAM) cell array comprising:
a plurality of MRAM cells;
a plurality of connecting vias, wherein each of the plurality of the connecting vias is connected one of the plurality of MRAM cells;
a first dielectric layer located adjacent to a bottom section of the plurality of connecting vias;
an etch stop layer located on top of the first dielectric layer, wherein a first portion of the etch stop layer is comprised of multiple layers, wherein a second portion of the etch stop layer is comprised of fewer layer than the first portion; and
a second dielectric layer located directly adjacent to an upper section of the plurality of connecting vias, wherein the second dielectric layer is direct contact with a portion of the etch stop layer.

8. The MRAM cell array of claim 7, wherein the first portion of the etch stop layer that is located between the first dielectric layer and the second dielectric layer has a first thickness.

9. The MRAM cell array of claim 8, wherein the first portion of the etch stop layer is comprised of three or more layers.

10. The MRAM cell array of claim 9, further comprising:
a spacer layer located on top of the etch stop layer.

11. The MRAM cell array of claim 10, wherein the spacer layer is in contact with a vertical side surface of the first portion of the etch stop layer.

12. The MRAM cell array of claim 11, wherein a second portion of the etch stop layer located between the first dielectric layer and the spacer layer has a second thickness, wherein the spacer layer is in direct contact with the etch stop layer.

13. The MRAM cell array of claim 12, wherein the second portion of the etch stop layer is comprised of two layers.

14. The MRAM cell array of claim 12, wherein the second portion of the etch stop layer is comprised of one layer.

15. The MRAM cell array of claim 12, wherein the first thickness is greater than the second thickness.

16. The MRAM cell array of claim 7, wherein a thickness of the etch stop layer varies between the first portion and the second portion.

17. A method of forming a magnetoresistive-random-access-memory (MRAM) cell array comprising:
forming a plurality of connecting vias;
forming a first dielectric layer located adjacent to a bottom section of the plurality of connecting vias;
forming an etch stop layer located on top of the first dielectric layer;
forming a second dielectric layer located directly adjacent to an upper section of the plurality of connecting vias;
forming a bottom electrode layer on top of the second dielectric layer and the plurality of connecting vias;
forming a magnetic-tunnel-junction (MTJ) layer on top of the bottom electrode;
forming a top electrode layer on the MTJ layer; and
utilizing an etching process to form a plurality of MRAM cells, wherein the etching process causes variations in a thickness of the etch stop layer.

18. The method of forming the MRAM cell array of claim 17, wherein a first portion of the etch stop layer that is located between the first dielectric layer and the second dielectric layer has a first thickness.

19. The method of forming the MRAM cell array of claim 18, further comprising:
forming a spacer layer located on top of the etch stop layer, wherein the spacer layer is in contact with a vertical side surface of the first portion of the etch stop layer.

20. The method of forming the MRAM cell array of claim 19, wherein a second portion of the etch stop layer located between the first dielectric layer and the spacer layer has a second thickness, wherein the spacer layer is in direct contact with the etch stop layer, wherein the first thickness is greater than the second thickness.
